(19) United States
(12) Patent Application Publication
(10) Pub. No.: US 2026/0226316 A1
(43) Pub. Date: Aug. 6, 2026

(54) POLISHING SLURRY COMPOSITION

(71) Applicant: KCTECH CO., LTD., Anseong-si (KR)

(72) Inventors: Se Jin Lim, Anseong-si (KR); Hyun Goo Kong, Anseong-si (KR); Jin Sook Hwang, Anseong-si (KR); Yun Su Kim, Anseong-si (KR)

(73) Assignee: KCTECH CO., LTD., Anseong-si, GY (KR)

(21) Appl. No.: 19/152,473

(22) PCT Filed: Jan. 9, 2024
(86) PCT No.: PCT/KR2024/000385

§ 371 Date: Jul. 31, 2025

(30) Foreign Application Priority Data
Feb. 1, 2023 (KR) 10-2023-0013479

(51) Int. Cl. C09G 1/02; C09K 3/14

(52) U.S. Cl. CPC C09G 1/02; C09K 3/1409

(57) ABSTRACT

The present invention relates to a polishing slurry composition comprising: polishing particles; a polishing inhibitor; and a surface roughness improver, wherein the surface roughness improver comprises a cationic quaternary ammonium salt polymer. The composition has an excellent surface-roughness improvement effect during polishing.

### TECHNICAL FIELD

The present disclosure relates to a polishing slurry composition.

### BACKGROUND ART

Semiconductor devices provide various circuits necessary for operation in the form of modules, and these modules become units with independent functions as parts of a single system. In order to manufacture a semiconductor device, a designer first designs the layout of circuit patterns according to the characteristics of a semiconductor chip using design rules.

Recently, as the design rules of semiconductors have been reduced, the structures have become narrower and taller, and an aspect ratio (depth/bottom width) has increased rapidly. The impact of scratches that occurred in a previous 50-nanometer semiconductor process has more than twice the impact in a 30-nanometer semiconductor process. This makes a surface of a film sensitive to not only scratches but also topography. The most important factors to consider in the polishing process include the amount of polishing and the quality of a polished surface. Recently, as the semiconductor design rules have been reduced, the importance of the quality of the polished surface has been maximized, and a polishing process for this purpose is being added.

Meanwhile, as the integration of semiconductors has increased recently, lower current leakage is required, and high-k dielectrics and metal gate structures have been designed to meet this requirement. Aluminum has been widely used as a metal gate material, but due to problems such as the difficulty of complete deposition and the difficulty of polishing aluminum oxide with high hardness as the design rule decreases, research has been conducted recently on using tungsten as a gate material.

However, as the constituent material changes from an aluminum gate to a tungsten gate, tungsten forms a topography by the tungsten grain size after deposition, which causes a phenomenon in which an undesired short between metals is generated, thereby reducing a semiconductor yield. To improve the polishing surface quality of the tungsten, that is, to improve topography, polishing is essential for the next-generation process. A slurry composition that does not improve topography causes tungsten overetching or unetching in the post-polishing process, resulting in process defects or unstable device operation, which drastically reduces the semiconductor yield.

In addition, although a high polishing rate may be secured by increasing the particle content, the chemical etching rate increases, making it difficult to control surface roughness, and the surface of a tungsten film becomes uneven and tungsten surface resistance increases, which deteriorates the electrical properties of tungsten. (PATENT DOCUMENT 1) Korean Laid-Open Patent Publication No. 2005-0074834

### DISCLOSURE OF THE INVENTION

### Technical Goals

An object of the present disclosure is to provide a polishing slurry composition capable of improving surface roughness of a polishing target film during polishing in response to the above-described needs.

However, technical goals to be achieved are not limited to those described above, and other goals not mentioned above can be clearly understood by one of ordinary skill in the art from the following description.

### Technical Solutions

The present disclosure provides a polishing slurry composition including:
abrasive particles; a polishing inhibitor including one or more primary amines; and
a surface roughness improver,
wherein the surface roughness improver includes a cationic quaternary ammonium salt polymer.

According to an embodiment, the cationic quaternary ammonium salt polymer may include
one or more selected from the group consisting of poly[bis(2-chloroethyl) etheralt-1,3-bis[3-(dimethylamino)propyl]urea]; poly(diallyldimethyl ammonium chloride; ethanol, 2,2′,2″-nitrilotris-, polymer with 1,4-dichloro-2-butene and N,N,N′,N′-tetramethyl-2-butene-1,4-diamine; a hydroxyethyl cellulose dimethyl diallylammonium chloride copolymer; a copolymer of acrylamide and diallyldimethylammonium chloride; a copolymer of acrylamide and quaternized dimethylammoniumethyl methacrylate; a copolymer of acrylic acid and diallyldimethylammonium chloride; an acrylamide-dimethylaminoethyl methacrylate methyl chloride copolymer; quaternized hydroxyethyl cellulose; a copolymer of vinylpyrrolidone and quaternized dimethylaminoethyl methacrylate; a copolymer of vinylpyrrolidone and quaternized vinylimidazole; a copolymer of vinylpyrrolidone and methacrylamidopropyl trimethylammonium; poly(2-methacryloxyethyltrimethylammonium chloride); poly(acrylamide 2-methacryloxyethyltrimethyl ammonium chloride); poly[2-(dimethylaminoethyl methacrylate methyl chloride]; poly[3-acrylamidopropyl trimethylammonium chloride]; poly[3-methacrylamidopropyl trimethylammonium chloride]; poly[oxyethylene(dimethylimino)ethylene (dimethylimino)ethylene dichloride]; a terpolymer of acrylic acid, acrylamide and diallyldimethylammonium chloride; a terpolymer of acrylic acid, methacrylamidopropyl trimethylammonium chloride, and methyl acrylate, and a terpolymer of vinylcaprolactam, vinylpyrrolidone, and quaternized vinylimidazole; poly(2-methacryloxyethyl phosphorylcholine-co-n-butyl methacrylate); poly[(dimethylamino)ethyl acrylate benzyl chloride quaternary salt] (PDMAEA BCQ), and poly[(dimethylamino)ethylacrylate methyl chloride quaternary salt] (PDMAEA MCQ).

According to an embodiment, a weight average molecular weight of the cationic quaternary ammonium salt polymer may be 20,000 to 2,000,000.

According to an embodiment, the surface roughness improver may be present in an amount of 0.0001 wt % to 0.3 wt % in the polishing slurry composition.

According to an embodiment, the primary amines may include one or more selected from the group consisting of aniline, cysteine, valine, arginine, ethylamine, histidine, methionine, serine, glutamine, glutamic acid, glycine, alanine, leucine, isoleucine, lysine, threonine, aspartic acid, asparagine, phenylalanine, deoxyphenylalanine, tyrosine, tryptophan, ornithine, citrulline, homoserine, triiodotyrosine, thyroxine, and proline.

According to an embodiment, the polishing inhibitor may be present in an amount of 0.005 wt % to 5 wt % in the polishing slurry composition.

According to an embodiment, the abrasive particles may include at least one selected from the group consisting of metal oxide, metal oxide coated with an organic or inorganic substance, and colloidal metal oxide, and the metal oxide may include at least one selected from the group consisting of silica, ceria, zirconia, alumina, titania, barium titania, germania, mangania, and magnesia.

According to an embodiment, the abrasive particles may be colloidal silica.

According to an embodiment, the abrasive particles may have an average diameter of 20 to 200 nanometers (nm).

According to an embodiment, the abrasive particles may be present in an amount of 0.1 wt % to 10 wt % in the abrasive slurry composition.

According to an embodiment, a pH of the polishing slurry composition may be 2 to 6.

According to an embodiment, a polishing target film of the polishing slurry composition may include one or more selected from the group consisting of tungsten, molybdenum, copper, tantalum, titanium, cobalt, nickel, manganese, and ruthenium.

According to an embodiment, a root mean square average roughness (Rq) value of a surface of a polishing target film after performing polishing using the polishing slurry composition may be 10 Å or less.

According to an embodiment, the polishing slurry composition may further include an oxidizer, and a catalyst.

According to an embodiment, the oxidizer may include at least one selected from the group consisting of hydrogen peroxide, urea hydrogen peroxide, urea, percarbonate, periodic acid, periodate, perchloric acid, perchlorate, perbromic acid, perbromate, perboric acid, perborate, permanganic acid, permanganate, persulfate, bromate, chlorate, chlorite, chromate, iodate, iodic acid, ammonium peroxide, calcium peroxide, barium peroxide, sodium peroxide, urea peroxide, and benzoyl peroxide.

According to an embodiment, the oxidizer may be present in an amount of 0.01 wt % to 5 wt % in the polishing slurry composition.

According to an embodiment, the catalyst may include at least one selected from the group consisting of iron (III) nitrate, iron (II) nitrate, iron (II) sulfate, iron (III) sulfate, iron (II) formate, iron (III) formate, iron (II) acetate, iron (III) acetate, iron (II) carbonate, iron (III) carbonate, iron (II) chloride, iron (III) chloride, iron (II) bromide, iron (III) bromide, iron (II) iodide, iron (III) iodide, iron (II) hydroxide, iron (III) hydroxide, iron (II) oxide, iron (III) oxide, iron (II) acetylacetone, iron (III) acetylacetone, iron (II) monoxide, iron (III) monoxide, iron (III) citrate, iron (III) oxalate, iron (III) fumarate, iron (III) lactate, iron (III) perchlorate, ammonium iron (III) hexacyano acid, potassium iron (III) hexacyano acid, ammonium iron (III) sulfate, and potassium iron (III) sulfate.

According to an embodiment, the catalyst may be present in an amount of 0.0001 wt % to 0.01 wt % in the polishing slurry composition.

### Effects of the Invention

In the present disclosure, a polishing slurry composition according to an embodiment may improve surface roughness during polishing. This may improve electrical characteristics by lowering surface resistance and reducing current loss, and may secure quality stability in subsequent post-processing, enabling next-generation high-integration processes.

It should be understood that the effects of the present disclosure are not limited to the above-described effects, but are construed as including all effects that can be inferred from the configurations and features described in the following description or claims of the present disclosure.

### BRIEF DESCRIPTION OF DRAWINGS

FIG. 1 illustrates results of measuring surface roughness of examples and comparative examples of the present disclosure.

### BEST MODE FOR CARRYING OUT THE INVENTION

Hereinafter, embodiments will be described in detail with reference to the accompanying drawings. However, various alterations and modifications may be made to the embodiments. Here, the embodiments are not construed as limited to the disclosure. The embodiments should be understood to include all modifications, equivalents, and substitutions within the scope and spirit of the present disclosure.

The terminology used herein is for the purpose of describing particular embodiments only and is not to be limiting of the embodiments. As used herein, the singular form is intended to include the plural forms as well, unless the context clearly indicates otherwise. It will be further understood that the terms “comprises/comprising” and/or “includes/including” when used herein, specify the presence of stated features, integers, steps, operations, elements, and/or components, but do not preclude the presence or addition of one or more other features, integers, steps, operations, elements, components and/or groups thereof.

Unless otherwise defined, all terms including technical and scientific terms used herein have the same meaning as commonly understood by one of ordinary skill in the art to which the embodiments belong. Terms, such as those defined in commonly used dictionaries, are to be interpreted as having a meaning that is consistent with their meaning in the context of the relevant art and the present disclosure, and are not to be interpreted in an idealized or overly formal sense unless expressly so defined herein.

It will be understood that when a certain part “includes” a certain component, the part does not exclude another component but may further include another component.

The present disclosure provides abrasive particles; a polishing inhibitor including one or more primary amines; and a surface roughness improver; wherein the surface roughness improver includes a cationic quaternary ammonium salt polymer.

In an embodiment of the present disclosure, the cationic quaternary ammonium salt polymer includes one or more selected from the group consisting of poly[bis(2-chloroethyl) etheralt-1,3-bis[3-(dimethylamino)propyl]urea]; poly(diallyldimethyl ammonium chloride; ethanol, 2,2′,2″-nitrilotris-, polymer with 1,4-dichloro-2-butene and N,N,N′,N′-tetramethyl-2-butene-1,4-diamine; a hydroxyethyl cellulose dimethyl diallylammonium chloride copolymer; a copolymer of acrylamide and diallyldimethylammonium chloride; a copolymer of acrylamide and quaternized dimethylammoniumethyl methacrylate; a copolymer of acrylic acid and diallyldimethylammonium chloride; an acrylamide-dimethylaminoethyl methacrylate methyl chloride copolymer; quaternized hydroxyethyl cellulose; a copolymer of vinylpyrrolidone and quaternized dimethylaminoethyl methacrylate; a copolymer of vinylpyrrolidone and quaternized vinylimidazole; a copolymer of vinylpyrrolidone and methacrylamidopropyl trimethylammonium; poly(2-methacryloxyethyltrimethylammonium chloride); poly(acrylamide 2-methacryloxyethyltrimethyl ammonium chloride); poly[2-(dimethylaminoethyl methacrylate methyl chloride]; poly[3-acrylamidopropyl trimethylammonium chloride]; poly[3-methacrylamidopropyl trimethylammonium chloride]; poly[oxyethylene(dimethylimino)ethylene (dimethylimino)ethylene dichloride]; a terpolymer of acrylic acid, acrylamide and diallyldimethylammonium chloride; a terpolymer of acrylic acid, methacrylamidopropyl trimethylammonium chloride, and methyl acrylate, and a terpolymer of vinylcaprolactam, vinylpyrrolidone, and quaternized vinylimidazole; poly(2-methacryloxyethyl phosphorylcholine-co-n-butyl methacrylate); poly[(dimethylamino)ethyl acrylate benzyl chloride quaternary salt] (PDMAEA BCQ), and poly[(dimethylamino)ethylacrylate methyl chloride quaternary salt] (PDMAEA MCQ).

Desirably, the cationic quaternary ammonium salt polymer may be poly[bis(2-chloroethyl) etheralt-1,3-bis[3-(dimethylamino)propyl]urea] of Chemical Formula 1 below.

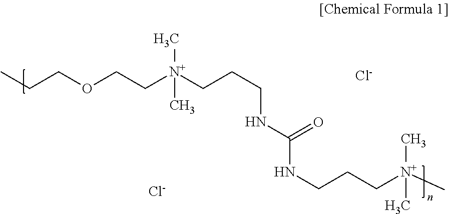

In an embodiment of the present disclosure, a weight average molecular weight of the cationic quaternary ammonium salt polymer may be 20,000 to 2,000,000.

In an embodiment of the present disclosure, the surface roughness improver may be used in an amount of 0.0001 wt % to 0.3 wt % in the polishing slurry composition. The surface roughness improver may be used in an amount of 0.0001 wt % to 0.3 wt % in the polishing slurry composition. When the amount of the surface roughness improver is less than 0.0001 wt % in the polishing slurry composition, the surface roughness improving effect may not be sufficient, and when the amount thereof exceeds 0.3 wt %, the polishing effect may be reduced. Desirably, the amount of the surface roughness improver may be 0.0005 to 0.1 wt %, and more desirably, when the amount thereof is 0.005 to 0.05 wt %, an excellent surface roughness improving effect may be exhibited.

In an embodiment, the polishing inhibitor may be primary amines. The primary amines may include at least one selected from the group consisting of aniline, cysteine, valine, arginine, ethylamine, histidine, methionine, serine, glutamine, glutamic acid, glycine, alanine, leucine, isoleucine, lysine, threonine, aspartic acid, asparagine, phenylalanine, deoxyphenylalanine, tyrosine, tryptophan, ornithine, citrulline, homoserine, triiodotyrosine, thyroxine, and proline.

In an embodiment, the polishing inhibitor may be present in an amount of 0.005 wt % to 5 wt % of the polishing slurry composition. When the amount of the polishing inhibitor is less than 0.005 wt % in the polishing slurry composition, it is difficult to achieve a desired polishing rate, and when the amount thereof exceeds 5 wt %, agglomeration may occur, resulting in a decrease in polishing performance.

The abrasive particles according to an embodiment of the present disclosure may include at least one selected from the group consisting of metal oxide, metal oxide coated with an organic or inorganic substance, and the metal oxide in a colloidal state, and the metal oxide may be at least one selected from the group consisting of silica, ceria, zirconia, alumina, titania, barium titania, germania, mangania, and magnesia. Desirably, colloidal silica abrasive particles that ensure excellent dispersibility under acidic conditions may be used.

In an embodiment of the present disclosure, for the abrasive particles, although a manufacturing method is not particularly limited as long as it is a metal oxide particle manufacturing method known in the technical field of the present disclosure, desirably, a hydrothermal synthesis method, a sol-gel method, a precipitation method, a co-precipitation method, a hydrothermal synthesis method, a filtering method, an aging method, a spray drying method, a thermal evaporation method, or the like may be used. The abrasive particles may include, but are not limited to, abrasive particles prepared by a liquid-phase method. The abrasive particles prepared by the liquid-phase method may be prepared by applying a sol-gel method in which abrasive particle precursors undergo a chemical reaction in an aqueous solution and crystals grow to obtain fine particles, a co-precipitation method in which abrasive particle ions are precipitated from an aqueous solution, a hydrothermal synthesis method in which abrasive particles are formed under a high temperature and high pressure, and the like. The abrasive particles prepared by the liquid-phase method may be dispersed so that surfaces of the abrasive particles have a positive charge.

As an example of the present disclosure, the abrasive particles may include at least one selected from the group consisting of spherical, square, needle-like, and plate-like shapes.

In an embodiment of the present disclosure, the abrasive particles may have an average diameter of 20 nm to 200 nm.

In an embodiment of the present disclosure, when the average diameter of the abrasive particles is less than 20 nm, excessive generation of small particles due to milling may result in reduced cleanability and excessive defects may occur on a surface of a substrate, wafer, or the like used in the polishing process. When the average diameter exceeds 200 nm, excessive polishing may occur, possibly resulting in dishing, erosion, and surface defects.

In an embodiment of the present disclosure, the abrasive particles may be included in an amount of 0.001 wt % to 30 wt %; 0.01 wt % to 20 wt %; or 0.1 wt % to 10 wt % in the abrasive slurry composition. When the amount of the abrasive particles in the slurry composition is less than 0.1 wt %, there is a problem that the polishing speed decreases, and when the amount thereof exceeds 10 wt %, the number of abrasive particles remaining on a surface of a polishing target film may increase due to an increase in the amount of the abrasive particles, and secondary defects such as dishing and/or erosion in a pattern due to over-polishing may occur.

According to an embodiment, a pH of the polishing slurry composition is in the range of 2 to 6, so that the abrasive particles, particularly colloidal silica particles, may be effectively dispersed within the composition, thereby improving polishing uniformity.

According to an embodiment, the polishing target film of the polishing slurry composition may be one or more selected from the group consisting of tungsten, molybdenum, copper, tantalum, titanium, cobalt, nickel, manganese, and ruthenium. In particular, the polishing target film of the present disclosure is a tungsten film (tungsten oxide film), and the polishing slurry of the present disclosure has improved surface roughness in the polishing of a tungsten film, which was difficult to have a uniform surface after polishing.

According to an embodiment, a root mean square average roughness (Rq) value of the surface of the polishing target film after polishing using the polishing slurry composition may be 10 Å or less. The Rq value is the surface roughness of tungsten inside a pattern having a size of 0.18 μm, measured using AFM (Bruker) analysis equipment.

According to an embodiment, the polishing slurry composition further includes an oxidizer and a catalyst.

According to an embodiment, the oxidizer may include at least one selected from the group consisting of hydrogen peroxide, urea hydrogen peroxide, urea, percarbonate, periodic acid, periodate, perchloric acid, perchlorate, perbromic acid, perbromate, perboric acid, perborate, permanganic acid, permanganate, persulfate, bromate, chlorate, chlorite, chromate, iodate, iodic acid, ammonium peroxide, calcium peroxide, barium peroxide, sodium peroxide, urea peroxide, and benzoyl peroxide.

According to an embodiment, the oxidizer may be included in an amount of 0.01 wt % to 5 wt % in the polishing slurry composition. When the oxidizer is less than 0.01 wt % in the polishing slurry composition, a polishing speed and an oxidation speed may decrease, and when the amount thereof exceeds 5 wt %, a film surface may be excessively etched, causing secondary problems such as dishing or erosion in a pattern.

According to an embodiment, the catalyst may include at least one selected from the group consisting of iron (III) nitrate, iron (II) nitrate, iron (II) sulfate, iron (III) sulfate, iron (II) formate, iron (III) formate, iron (II) acetate, iron (III) acetate, iron (II) carbonate, iron (III) carbonate, iron (II) chloride, iron (III) chloride, iron (II) bromide, iron (III) bromide, iron (II) iodide, iron (III) iodide, iron (II) hydroxide, iron (III) hydroxide, iron (II) oxide, iron (III) oxide, iron (II) acetylacetone, iron (III) acetylacetone, iron (II) monoxide, iron (III) monoxide, iron (III) citrate, iron (III) oxalate, iron (III) fumarate, iron (III) lactate, iron (III) perchlorate, ammonium iron (III) hexacyano acid, potassium iron (III) hexacyano acid, ammonium iron (III) sulfate, and potassium iron (III) sulfate.

According to an embodiment, the catalyst may be included in an amount of 0.0001 wt % to 0.01 wt % in the polishing slurry composition. When the amount of the catalyst is less than 0.0001 wt % in the composition, a synergistic effect of the polishing and the tungsten film oxidation may not be sufficiently obtained, and when the amount thereof exceeds 0.01 wt %, iron atoms may be used, which may cause difficulty in controlling the polishing speed.

Hereinafter, the present disclosure will be described in detail with reference to the following examples and comparative examples. However, the technical idea of the present disclosure should not be construed as limited thereto.

### Examples 1 to 6

A slurry composition was prepared by mixing 125 nm colloidal silica particles (included in an amount of 3 wt % in the composition), hydrogen peroxide, iron (III) nitrate (included in an amount of 0.001 wt % in the composition), a polishing inhibitor, and a surface roughness improver according to Table 1. After adding the above materials, the materials were mixed for 6 hours using a bead milling machine.

A cationic quaternary ammonium salt polymer of Chemical Formula 1 below was used as the surface roughness improver, and valine was used as the polishing inhibitor.

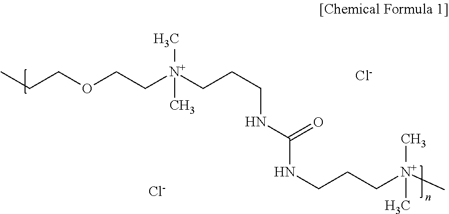

### Comparative Example 1

In this comparative example, a polishing slurry composition was prepared in the same manner as in Examples 1 to 6, without using the cationic quaternary ammonium salt polymer which is the surface roughness improver.

### Comparative Example 2

In this comparative example, a polishing slurry composition was prepared in the same manner as in Examples 1 to 6, without using the cationic quaternary ammonium salt polymer which is the surface roughness improver and primary amine which is the polishing inhibitor.

### Comparative Example 3

In this comparative example, a polishing slurry composition was prepared in the same manner as in Example 1, but using ammonium hydroxide, a quaternary ammonium compound, instead of the surface roughness improver.

TABLE 1

| | Abrasive | Surface roughness | Oxidation | Primary | H₂O₂ | |
|---|---|---|---|---|---|---|
| | particles | improver (wt %) | catalyst | amines | (wt %) | pH |
| Example 1 | Silica | Cationic quaternary | 0.001 | 0.1 | 0.18 | 2.3 |
| | | ammonium salt | | | | |
| | | polymer (0.01 wt %) | | | | |
| Example 2 | Silica | Cationic quaternary | 0.001 | 0.1 | 0.18 | 2.3 |
| | | ammonium salt | | | | |
| | | polymer (0.007 wt %) | | | | |
| Example 3 | Silica | Cationic quaternary | 0.001 | 0.1 | 0.18 | 2.3 |
| | | ammonium salt | | | | |
| | | polymer (0.005 wt %) | | | | |
| Example 4 | Silica | Cationic quaternary | 0.001 | 0.1 | 0.18 | 2.3 |
| | | ammonium salt | | | | |
| | | polymer (0.003 wt %) | | | | |
| Example 5 | Silica | Cationic quaternary | 0.001 | 0.1 | 0.18 | 2.3 |
| | | ammonium salt | | | | |
| | | polymer (0.001 wt %) | | | | |
| Example 6 | Silica | Cationic quaternary | 0.001 | 0.1 | 0.18 | 2.3 |
| | | ammonium salt | | | | |
| | | polymer (0.0005 wt %) | | | | |
| Comparative | Silica | — | 0.001 | 0.1 | 0.18 | 2.3 |
| Example 1 | | | | | | |
| Comparative | Silica | — | 0.001 | — | 0.18 | 2.3 |
| Example 2 | | | | | | |
| Comparative | Silica | Ammonium hydroxide | 0.001 | 0.1 | 0.18 | 2.3 |
| Example 3 | | (0.01 wt %) | | | | |

### <Experimental Example> Measurement of Polishing Performance of Polishing Slurry Composition

A wafer was polished using the polishing slurry compositions of Examples and Comparative Examples under the following polishing conditions. 5

### [Chemical Mechanical Polishing (CMP) Polishing Conditions]

Evaluation equipment and polishing wafer: AP-300 (CTS) and MIT 754 300 mm PTW

Process conditions: Speed 100/103 rpm, Pressure 2 psi, Flow rate 200 mL/min

An Ox layer of a patterned wafer with a tungsten/oxide film was analyzed after polishing to the same thickness.

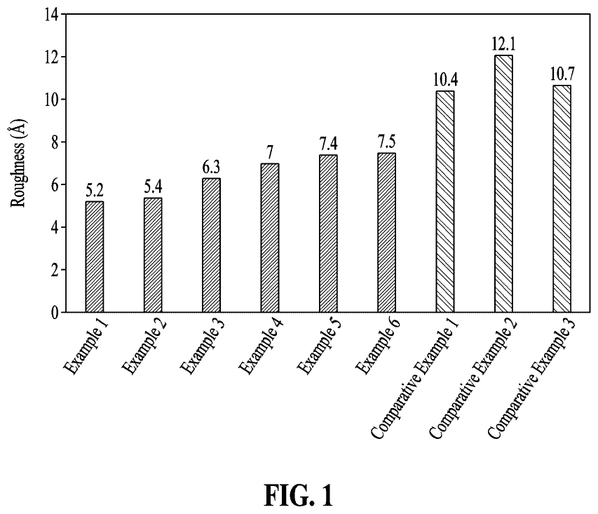

To analyze the surface roughness, the surface roughness of tungsten inside a pattern with a size of 0.18 μm was measured using an AFM (Bruker) analysis device and compared as the Rq value. The results thereof are shown in Table 2 and FIG. 1.

TABLE 2

| | Rq (Å) |
|---|---|
| Example 1 | 5.2 |
| Example 2 | 5.4 |
| Example 3 | 6.3 |
| Example 4 | 7 |
| Example 5 | 7.4 |
| Example 6 | 7.5 |
| Comparative Example 1 | 10.4 |
| Comparative Example 2 | 12.1 |
| Comparative Example 3 | 10.7 |

As may be confirmed in Table 1 and FIG. 1, the wafers using the compositions of Examples 1 to 6 including the cationic quaternary ammonium salt polymer according to the present disclosure had lower Rq values compared to the surface of a wafer using the composition of Comparative Example 1 not including the cationic quaternary ammonium salt polymer. In addition, it was confirmed that, in Comparative Example 2 not including the cationic quaternary ammonium salt polymer and the primary amine, the surface roughness was higher, and in Comparative Example 3, the Rq value was 10 Å or more.

Therefore, it was confirmed that the polishing slurry composition of the present disclosure has an excellent effect of improving the surface roughness during polishing.

While the embodiments are described with reference to drawings, it will be apparent to one of ordinary skill in the art that various alterations and modifications in form and details may be made in these embodiments without departing from the spirit and scope of the claims and their equivalents. For example, suitable results may be achieved if the described techniques are performed in a different order, and/or if components in a described system, architecture, device, or circuit are combined in a different manner, and/or replaced or supplemented by other components or their equivalents.

Therefore, other implementations, other embodiments, and equivalents to the claims are also within the scope of the following claims.

1. A polishing slurry composition comprising:
abrasive particles;
a polishing inhibitor comprising one or more primary amines; and
a surface roughness improver;
wherein the surface roughness improver comprises a cationic quaternary ammonium salt polymer.

2. The polishing slurry composition of claim 1, wherein the cationic quaternary ammonium salt polymer comprises one or more selected from the group consisting of poly[bis(2-chloroethyl) etheralt-1,3-bis[3-(dimethylamino)propyl]urea]; poly(diallyldimethyl ammonium chloride; ethanol, 2,2′,2″-nitrilotris-, polymer with 1,4-dichloro-2-butene and N,N,N′,N′-tetramethyl-2-butene-1,4-diamine; a hydroxyethyl cellulose dimethyl diallylammonium chloride copolymer; a copolymer of acrylamide and diallyldimethylammonium chloride; a copolymer of acrylamide and quaternized dimethylammoniumethyl methacrylate; a copolymer of acrylic acid and diallyldimethylammonium chloride; an acrylamide-dimethylaminoethyl methacrylate methyl chloride copolymer; quaternized hydroxyethyl cellulose; a copolymer of vinylpyrrolidone and quaternized dimethylaminoethyl methacrylate; a copolymer of vinylpyrrolidone and quaternized vinylimidazole; a copolymer of vinylpyrrolidone and methacrylamidopropyl trimethylammonium; poly(2-methacryloxyethyltrimethylammonium chloride); poly(acrylamide 2-methacryloxyethyltrimethyl ammonium chloride); poly[2-(dimethylaminoethyl methacrylate methyl chloride]; poly[3-acrylamidopropyl trimethylammonium chloride]; poly[3-methacrylamidopropyl trimethylammonium chloride]; poly[oxyethylene(dimethylimino)ethylene (dimethylimino)ethylene dichloride]; a terpolymer of acrylic acid, acrylamide and diallyldimethylammonium chloride; a terpolymer of acrylic acid, methacrylamidopropyl trimethylammonium chloride, and methyl acrylate, and a terpolymer of vinylcaprolactam, vinylpyrrolidone, and quaternized vinylimidazole; poly(2-methacryloxyethyl phosphorylcholine-co-n-butyl methacrylate); poly[(dimethylamino)ethyl acrylate benzyl chloride quaternary salt] (PDMAEA BCQ), and poly[(dimethylamino)ethylacrylate methyl chloride quaternary salt] (PDMAEA MCQ).

3. The polishing slurry composition of claim 1, wherein a weight average molecular weight of the cationic quaternary ammonium salt polymer is 20,000 to 2,000,000.

4. The polishing slurry composition of claim 1, wherein the surface roughness improver is present in an amount of 0.0001 wt % to 0.3 wt % in the polishing slurry composition.

5. The polishing slurry composition of claim 1, wherein the primary amines comprise one or more selected from the group consisting of aniline, cysteine, valine, arginine, ethylamine, histidine, methionine, serine, glutamine, glutamic acid, glycine, alanine, leucine, isoleucine, lysine, threonine, aspartic acid, asparagine, phenylalanine, deoxyphenylalanine, tyrosine, tryptophan, ornithine, citrulline, homoserine, triiodotyrosine, thyroxine, and proline.

6. The polishing slurry composition of claim 1, wherein the polishing inhibitor is present in an amount of 0.005 wt % to 5 wt % in the polishing slurry composition.

7. The polishing slurry composition of claim 1, wherein
the abrasive particles comprise at least one selected from the group consisting of metal oxide, metal oxide coated with an organic or inorganic substance, and colloidal metal oxide, and
the metal oxide comprises at least one selected from the group consisting of silica, ceria, zirconia, alumina, titania, barium titania, germania, mangania, and magnesia.

8. The polishing slurry composition of claim 7, wherein the abrasive particles are colloidal silica.

9. The polishing slurry composition of claim 1, wherein the abrasive particles has an average diameter of 20 to 200 nanometers (nm).

10. The polishing slurry composition of claim 1, wherein the abrasive particles are present in an amount of 0.1 wt % to 10 wt % in the abrasive slurry composition.

11. The polishing slurry composition of claim 1, wherein a pH of the polishing slurry composition is 2 to 6.

12. The polishing slurry composition of claim 1, wherein a polishing target film of the polishing slurry composition comprises one or more selected from the group consisting of tungsten, molybdenum, copper, tantalum, titanium, cobalt, nickel, manganese, and ruthenium.

13. The polishing slurry composition of claim 1, wherein a root mean square average roughness (Rq) value of a surface of a polishing target film after performing polishing using the polishing slurry composition is 10 Å or less.

14. The polishing slurry composition of claim 1, further comprising:
an oxidizer; and
a catalyst.

15. The polishing slurry composition of claim 14, wherein the oxidizer comprises at least one selected from the group consisting of hydrogen peroxide, urea hydrogen peroxide, urea, percarbonate, periodic acid, periodate, perchloric acid, perchlorate, perbromic acid, perbromate, perboric acid, perborate, permanganic acid, permanganate, persulfate, bromate, chlorate, chlorite, chromate, iodate, iodic acid, ammonium peroxide, calcium peroxide, barium peroxide, sodium peroxide, urea peroxide, and benzoyl peroxide.

16. The polishing slurry composition of claim 14, wherein the oxidizer is present in an amount of 0.01 wt % to 5 wt % in the polishing slurry composition.

17. The polishing slurry composition of claim 14, wherein the catalyst comprises at least one selected from the group consisting of iron (III) nitrate, iron (II) nitrate, iron (II) sulfate, iron (III) sulfate, iron (II) formate, iron (III) formate, iron (II) acetate, iron (III) acetate, iron (II) carbonate, iron (III) carbonate, iron (II) chloride, iron (III) chloride, iron (II) bromide, iron (III) bromide, iron (II) iodide, iron (III) iodide, iron (II) hydroxide, iron (III) hydroxide, iron (II) oxide, iron (III) oxide, iron (II) acetylacetone, iron (III) acetylacetone, iron (II) monoxide, iron (III) monoxide, iron (III) citrate, iron (III) oxalate, iron (III) fumarate, iron (III) lactate, iron (III) perchlorate, ammonium iron (III) hexacyano acid, potassium iron (III) hexacyano acid, ammonium iron (III) sulfate, and potassium iron (III) sulfate.

18. The polishing slurry composition of claim 14, wherein the catalyst is present in an amount of 0.0001 wt % to 0.01 wt % in the polishing slurry composition.
